(19) United States
(12) Patent Application Publication
(10) Pub. No.: US 2010/0173174 A1
(43) Pub. Date: Jul. 8, 2010

(54) PROCESS FOR PRODUCING MAGNETIC DEVICE, APPARATUS FOR PRODUCING MAGNETIC DEVICE, AND MAGNETIC DEVICE

(76) Inventor: Kenichi Imakita, Tsukuba-shi (JP)

Correspondence Address: Pearl Cohen Zedek Latzer, LLP, 1500 Broadway, 12th Floor, New York, NY, 10036, US

(21) Appl. No.: 12/663,484

(22) PCT Filed: May 28, 2008
(86) PCT No.: PCT/JP2008/059840

§ 371 Date: Dec. 7, 2009

(30) Foreign Application Priority Data
Jun. 11, 2007 (JP) 2007-154002

(51) Int. Cl. C23C 14/34

(52) U.S. Cl. 428/800; 204/192.1; 204/298.02

(57) ABSTRACT

A magnetic device manufacturing apparatus that increases the unidirectional anisotropy constant (JK). A substrate (S) is placed in a substrate holder (24) in a film formation area (21a), the substrate (S) is heated to a predetermined temperature, and the processing pressure is reduced to 0.1 (Pa) or lower. A target (T2) of which a main component is an element forming the antiferromagnetic layer is sputtered with at least either one of Kr and Xe to form an antiferromagnetic layer. The antiferromagnetic layer includes an L1₂ ordered phase expressed by compositional formula Mn_{100-X}-M_{X} (where M is at least one element selected from the group consisting of Ru, Rh, Ir, and Pt, and X is 20(atom %)≦X≦30(atom %)).

### TECHNICAL FIELD

The present invention relates to a method for manufacturing a magnetic device, an apparatus for manufacturing a magnetic device, and a magnetic device.

### BACKGROUND ART

Magnetoresistance elements implementing a giant magnetoresistance (GMR) effect or a tunnel magnetoresistance (TMR) effect has a superior magnetoresistance change rate and is thus used in magnetic devices, such as magnetic sensors, magnetic reproduction heads, and magnetic memories.

A magnetoresistance element, which has an artificial lattice structure of about six to fifteen layers, includes a free layer having a rotatable spontaneous magnetization direction, a fixed layer having a fixed spontaneous magnetization direction, a non-magnetic layer arranged between the fixed layer and free layer, and an antiferromagnetic layer that induces unidirectional anisotropy relative to the fixed layer.

Known antiferromagnetic layers include a manganese iridium (MnIr) thin film and a platinum manganese (PtMn) thin film (for example, refer to patent document 1 and patent document 2). The MnIr thin film generates a strong magnetic coercive force with the fixed layer. The PtMn thin film applies superior thermal stability to the magnetic coercive force.

The magnetic coercive force between the antiferromagnetic layer and the fixed layer is generally evaluated using a unidirectional anisotropy constant J_{K}. The unidirectional anisotropy constant J_{K} of a superimposed film including the antiferromagnetic layer and the fixed layer is obtained from J_{K}=M_{S}·d_{F}·Hₑₓ. Here, M_{S} represents saturated magnetization of the fixed layer, d_{F} represents the thickness of the fixed layer, and Hₑₓ represents the level of a shift magnetic field in a magnetic hysteresis curve.

In an ultrathin MnIr film of which thickness is five to ten nanometers, as the composition ratio of Mn and Ir becomes 3:1, and the crystal structure is ordered in accordance with an L1₂ type, an extremely large unidirectional anisotropy constant J_{K} is obtained. In the Mn₃Ir thin film, the temperature at which the magnetic coercive force is dissipated, or the so-called blocking temperature, is 360° or greater. Thus, the Mn₃Ir thin film has high thermal stability with regard to magnetism (patent document 3).

To manufacture the antiferromagnetic layer, generally, sputtering is performed using argon (Ar) gas having a high purity. A high-pressure process in which the pressure during sputtering exceeds 1.0 (Pa) raises the substrate temperature T_{sub} and thereby increases the unidirectional anisotropy constant J_{K}.

FIG. 8 shows the unidirectional anisotropy constant J_{K} when using MnIr for the antiferromagnetic layer and CoFe for the fixed layer. In FIG. 8, the sputtering pressure is 2.0 (Pa), and the substrate temperature T_{sub} is room temperature (20° C.) to 400° C. Further, the vertical axis represents the unidirectional anisotropy constant J_{K}, and the horizontal axis represents the applied power density P_{D} for a target of which main components are Mn and Ir.

As shown in FIG. 8, the unidirectional anisotropy constant J_{K} increases as the applied power density P_{D} increases. Further, when the applied power density P_{D} is the same, the unidirectional anisotropy constant J_{K} increases as the substrate temperature T_{sub} increases. The unidirectional anisotropy constant J_{K} of a superimposed film reaches a maximum value in the vicinity of Mn₃Ir at which the composition ratio of Mn and Ir becomes 3:1. The dependency of the applied power density P_{D} suggests that an increase in the applied power density P_{D} brings the composition of the MnIr thin film close to Mn₃Ir. Further, the dependency of the substrate temperature T_{sub} suggests that a rise in the substrate temperature T_{sub} enhances the formation of an L1₂ ordered phase.

However, the formation of an antiferromagnetic layer with the high-pressure process described above leads to shortcomings that will now be described. Among the sputtered particles, particles such as Ir particles have a large mass. Even if such large-mass particles collide against Ar particles, the kinetic direction of the large-mass particles barely changes. In contrast, when particles having a small mass such as Mn particles collide against residual Ar particles, the kinetic direction of the small-mass particles easily changes. As a result, the high-pressure process causes large variations in the composition and film thickness of the antiferromagnetic layer within the plane surface of the substrate. In a magnetic device that requires thickness uniformity and allows for each layer to have a thickness variation range of one nanometer or less, variations in the composition and film thickness of the antiferromagnetic layer would significantly deteriorate the magnetic characteristics of the device.

The afore-mentioned shortcomings may be resolved by lowering the sputtering pressure. However, according to experiments conducted by the inventor of the present invention, when the pressure during sputtering is reduced to 0.1 (Pa) or lower, a sufficient unidirectional anisotropy constant J_{K} for the superimposed film cannot be obtained regardless of the applied power density P_{D} or the substrate temperature T_{sub}.

FIG. 9 shows the unidirectional anisotropy constant J_{K} when using MnIr for the antiferromagnetic layer and CoFe for the fixed layer. In FIG. 8, the substrate temperature T_{sub} is room temperature (20° C.) or 350° C., and the applied power density P_{D} is 0.41 (W/cm²) to 2.44 (W/cm²). Further, the vertical axis represents the unidirectional anisotropy constant J_{K}, and the horizontal axis represents the sputtering pressure (hereinafter simply referred to as the processing pressure P_{S}).

As shown in FIG. 9, when the substrate temperature T_{sub} is 350° C., the unidirectional anisotropy constant J_{K} gradually decreases as the processing pressure P_{S} decreases and ultimately reaches a level (approximately 0.4 (erg/cm²)) that is about the same as the unidirectional anisotropy constant J_{K} for when the substrate temperature T_{sub} is the room temperature (20° C.). In contrast, when the substrate temperature T_{sub} is the room temperature, the unidirectional anisotropy constant J_{K} gradually increases as the processing pressure P_{S} decreases but does not exceed the unidirectional anisotropy constant J_{K} for when the substrate temperature T_{sub} is 350° C.

Patent Document 1: Japanese Patent No. 2672802

Patent Document 2: Japanese Patent No. 2962415

Patent Document 3: Japanese Laid-Open Patent Publication No. 2005-333106

### DISCLOSURE OF THE INVENTION

The present invention provides a method for manufacturing a magnetic device, an apparatus for manufacturing a magnetic device, and a magnetic device manufactured by the manufacturing apparatus that increases the unidirectional anisotropy constant J_{K} in a low-pressure process when the pressure during sputtering is 0.1 (Pa) or less.

One aspect of the present invention is a method for manufacturing a magnetic device. The method includes arranging a substrate in a film formation chamber, heating the substrate to a predetermined temperature, reducing the pressure of the film formation chamber to 0.1 (Pa) or lower, and forming an antiferromagnetic layer on the substrate in the film formation chamber of which the pressure is reduced by sputtering a target of which a main component is an element forming the antiferromagnetic layer with at least either one of Kr and Xe. The antiferromagnetic layer includes an L1₂ ordered phase expressed by compositional formula Mn_{100-X}-M_{X} (where M is at least one element selected from the group consisting of Ru, Rh, Ir, and Pt, and X is 20(atom %)≦X≦30(atom %)).

A further aspect of the present invention is an apparatus for manufacturing a magnetic device. The apparatus includes a film formation chamber that accommodates a substrate, a pressure reduction unit that reduces the pressure of the film formation unit, a heating unit that heats the substrate in the film formation chamber, a cathode including a target of which a main component is an element forming an antiferromagnetic layer, a supply unit that supplies the film formation chamber with at least either one of Kr and Xe, a control unit that drives the heating unit to heat the substrate to a predetermined temperature, drives the pressure reduction unit to reduce the pressure of the film formation chamber to 0.1 (Pa) or lower, drives the supply unit to supply the film formation chamber with at least either one of Kr and Xe, and drives the cathode to sputter the target and form the antiferromagnetic layer on the substrate. The antiferromagnetic layer includes an L1₂ ordered phase expressed by compositional formula Mn_{100-X}-M_{X} (where M is at least one element selected from the group consisting of Ru, Rh, Ir, and Pt, and X is 20(atom %)≦X≦30(atom %)).

Another aspect of the present invention is a magnetic device manufactured by the above manufacturing apparatus.

### BRIEF DESCRIPTION OF THE DRAWINGS

FIG. 1 is a schematic diagram showing an apparatus for manufacturing a magnetic device;

FIG. 2 is a cross-sectional side view showing an antiferromagnetic layer chamber;

FIG. 3 is a diagram showing the dependency of the unidirectional anisotropy constant on the applied power density;

FIG. 4 is a diagram showing the dependency of the unidirectional anisotropy constant on the processing pressure;

FIG. 5 is a diagram showing the dependency of the resistance uniformity on the processing pressure;

FIG. 6 is a diagram showing the dependency of the resistance uniformity of an exchange-coupled magnetic field on the processing pressure;

FIG. 7 is a cross-sectional view showing the main part of a magnetic memory;

FIG. 8 is a diagram showing the dependency of the unidirectional anisotropy constant on the applied power density in the prior art; and

FIG. 9 is a diagram showing the dependency of the unidirectional anisotropy constant on the processing pressure in the prior art.

### BEST MODE FOR CARRYING OUT THE INVENTION

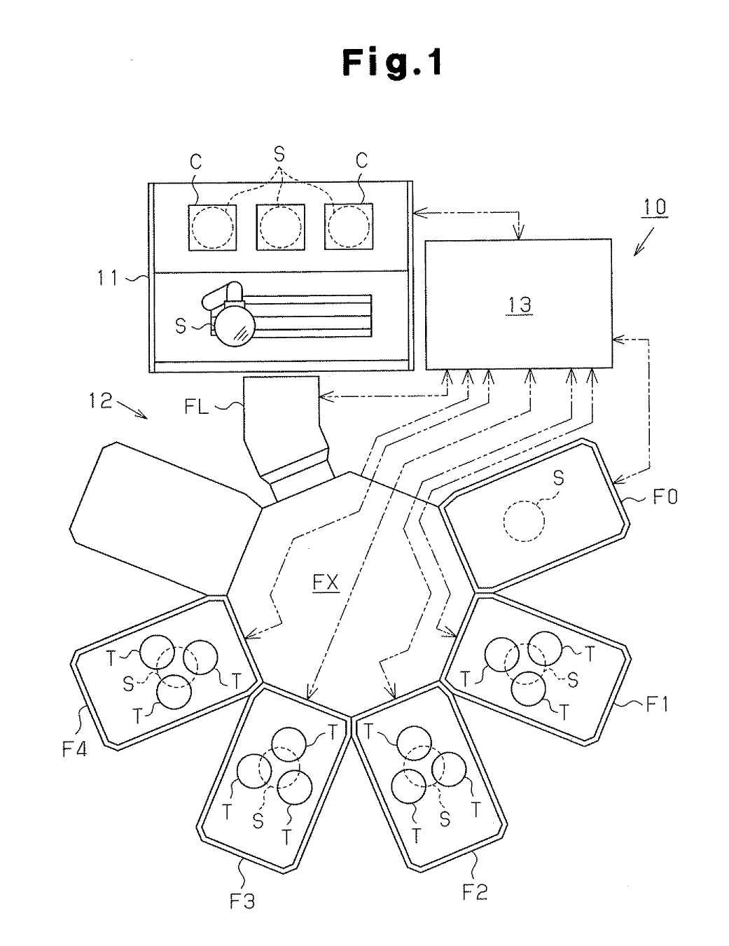

A magnetic device manufacturing apparatus 10 according to one embodiment of the present invention will now be discussed with reference to the drawings. FIG. 1 is a schematic diagram showing the magnetic device manufacturing apparatus 10. As shown in FIG. 1, the manufacturing apparatus 10 includes a conveying device 11, a film formation device 12, and a control device 13, which serves as a control unit.

The conveying device 11 includes cassettes C, which are capable of accommodating a plurality of substrates S, and a conveying robot, which conveys the substrates S. The conveying device 11 loads the substrates S from the cassettes C into the film formation device 12 when starting a film formation process on the substrates S and unloads the substrates S out of the film formation device 12 and onto the cassettes C when ending the film formation process on the substrates S. The substrates S may be formed from, for example, silicon, glass, AlTiC, or the like.

The film formation device 12 includes a transfer chamber FX connected to a load chamber FL, which loads and unloads substrates S, and a pre-processing chamber F0, which is for washing the surface of the substrates S. The transfer chamber FX is further connected to an antiferromagnetic layer chamber F1, which is for forming antiferromagnetic layers, and a fixed layer chamber F2, which is for forming fixed layers. The transfer chamber FX is also connected to a non-antiferromagnetic chamber F3, which is for forming non-antiferromagnetic layers, and a free layer chamber F4, which is for forming free layers.

When the film formation process of the substrates S starts, the load chamber FL receives the substrates S from the conveying device 11 and sends the substrates S to the transfer chamber FX. When the film formation process of the substrates S ends, the load chamber FL receives the substrates S from the transfer chamber FX and sends the substrates S to the conveying device 11.

The transfer chamber FX includes a transfer robot (not shown), which transfers the substrates S. When the film formation process of the substrates S starts, the transfer chamber FX sequentially transfers the substrates S to the pre-processing chamber F0, the antiferromagnetic layer chamber F1, the fixed layer chamber F2, the non-antiferromagnetic layer chamber F3, and the free layer chamber F4. When the film formation process of the substrates S ends, the transfer chamber FX transfers the substrates S from the free layer chamber F4 to the load chamber FL.

The pre-processing chamber F0 is a sputtering device that sputters the surface of the substrates S and sputter-washes the surface of the substrates S.

The antiferromagnetic layer chamber F1 is a sputtering device, which includes a target T for forming an underlayer electrode layer and a target T for forming an antiferromagnetic layer. The antiferromagnetic layer chamber F1 sputters each target T to form a metal film or antiferromagnetic film of which the composition is substantially the same as the elements forming each target T on the substrates S. Such a film having substantially the same composition includes a film composition of which the composition deviation from the target is 10 (atom %) or less.

The underlayer electrode layer includes a buffer layer, which moderates the surface roughness of the substrates S, and a seed layer, which determines the crystalline orientation of the antiferromagnetic layer. The underlayer electrode layer may be formed from tantalum (Ta), ruthenium (Ru), titanium (Ti), tungsten (W), chromium (Cr), or an alloy of these elements. The antiferromagnetic layer fixes the magnetization direction of a fixed layer in a single direction through a mutual action with the fixed layer. The antiferromagnetic layer is a thin film formed from an antiferromagnetic body including an L1₂ ordered phase expressed by compositional formula Mn_{100-X}-M_{X} (where M is at least one element selected from the group consisting of Ru, Rh, Ir, and Pt, and X is 20(atom %)≦X≦30(atom %)). The antiferromagnetic layer may be formed from, for example, iridium manganese (IrMn), platinum manganese (PtMn), or the like.

The fixed layer chamber F2 is a sputtering device including a plurality of targets T for forming the fixed layer. The fixed layer chamber F2 sputters each target T to form a ferromagnetic film of which the composition is substantially the same as the elements forming each target T on the substrates S. The fixed layer is a ferromagnetic layer of which the magnetization direction is fixed in a single direction through a mutual action with the antiferromagnetic layer. The fixed layer may be formed from cobalt iron (CoFe), cobalt iron boron (CoFeB), and nickel iron (NiFe). The fixed layer is not limited to a single-layer structure and may be a superimposed ferric structure formed from a ferromagnetic layer/magnetic coupling layer/ferromagnetic layer, for example, CoFe/Ru/CoFeB.

The non-magnetic layer chamber F3 is a sputtering device including a plurality of targets T for forming the non-magnetic layer. The non-magnetic layer chamber F3 sputters each target T to form a non-magnetic film of which composition is substantially the same as the elements forming each target T on the substrates S. The non-magnetic layer is a metal thin film having a thickness of 0.4 to 2.5 nm or an insulative film having a thickness that allows for the flow of tunneling current in a thicknesswise direction. The resistance value of the non-magnetic layer varies in accordance with whether the spontaneous magnetization of the fixed layer and spontaneous magnetization of the free layer are parallel. The non-magnetic layer may be formed from, for example, copper (Cu), aluminum (Al), magnesium (Mg), or an alloy of these elements. The non-magnetic layer may also be formed from magnesium oxide (MgO) or aluminum oxide (Al₂O₃).

The free layer chamber F4 is a sputtering device, which includes a target T for forming the free layer and a target T for forming a protective layer. The free layer chamber F4 sputters each target T to form a ferromagnetic film or metal film of which the composition is substantially the same as the elements forming each target T on the substrates S. The free layer has coercive force enabling rotation of the spontaneous magnetization direction and causes the spontaneous magnetization direction to be parallel or non-parallel to the spontaneous magnetization direction of the fixed layer. The free layer may be a single-layer structure of CoFe, CoFeB, or NiFe, a superimposed ferric structure of CoFeB/Ru/CoFeB, or a superimposed structure of CoFe and NiFe. The protective layer includes a barrier layer that moderates surface roughness of the substrates S or a buffer layer for ambient air. The protective layer may be formed from Ta, Ti, W, Cr, or an alloy of these elements.

Referring to FIG. 1, the control device 13 causes the manufacturing apparatus 10 to execute various processes. The control device 13 includes a CPU, which is for executing various types of computations, a RAM, which is for storing various types of data, and a ROM or hard disk, which is for storing various types of control programs. The control device 13 reads, for example, a transfer program from the hard disk, and transfers the substrates S to the chambers in accordance with the transfer program. Further, the control device 13 reads film formation conditions for each layer from the hard disk and executes a film formation process for each layer in accordance with the film formation conditions.

As shown by the double-dotted lines in FIG. 1, the control device 13 electrically connects the conveying device 11 and each chamber of the film formation device 12. The conveying device 11 uses various sensors (not shown) to detect the quantity and size of the substrates S that are subject to processing and provides the detection results to the control device 13. The control device 13 uses the detection result from the conveying device to generate a first drive control signal in correspondence with the conveying device 11 and provides the first drive control signal to the conveying device 11. The conveying device 11 executes a process for conveying the substrates S in response to the first drive control signal. The film formation device 12 uses various sensors (not shown) to detect the state, for example, for the presence of a substrate S and the pressure, of each chamber, such as the load chamber FL and the antiferromagnetic layer chamber F1 and provides the detection results to the control device 13. The control device 13 uses the detection results from the film formation device 12 to generate a second drive control signal in correspondence with the film formation device 12 and provides the second drive control signal to the film formation device 12. The film formation device 12 executes a process for forming a film on the substrates S in response to the second drive control signal.

The control device 13 then drives the conveying device 11 and the film formation device 12 to load the substrates S on the conveying device 11 into the pre-processing chamber F0 to sputter-wash the surface of the substrates S. Further, the control device 13 drives the film formation device 12 to sequentially transfer the substrates from the pro-processing chamber F0 to the antiferromagnetic layer chamber F1, the fixed layer chamber F2, the non-magnetic layer chamber F3, and the free layer chamber F4 so as to sequentially superimpose the underlayer electrode layer, the antiferromagnetic layer, the fixed layer, the non-magnetic layer, the free layer, and the protective layer on the surface of the washed substrates S. In this manner, the control device 13 forms a magnetoresistance element, which includes the underlayer electrode layer, the antiferromagnetic layer, the fixed layer, the non-magnetic layer, the free layer, and the protective layer.

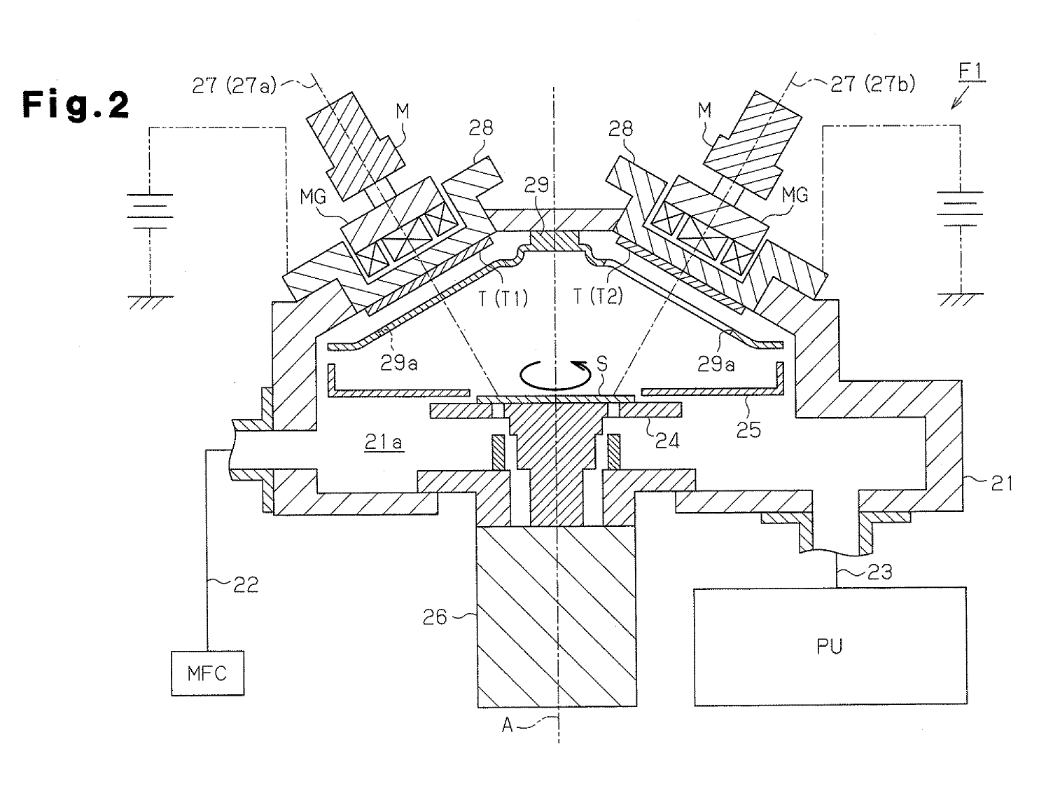

The antiferromagnetic layer chamber F1 will now be discussed. FIG. 2 is a cross-sectional side view showing the antiferromagnetic layer chamber F1.

As shown in FIG. 2, the antiferromagnetic chamber F1 includes a vacuum tank (hereinafter simply referred to as the film formation area 21a) connected to the transfer chamber FX and loads the substrates S from the transfer chamber FX into the interior of a chamber main body 21. In one embodiment, the interior of the chamber main body 21 is referred to as a film formation area 21a (film formation chamber).

The chamber main body 21 is connected via a supply pipe 22 to a mass flow controller MFC, which forms a supply unit. The mass flow controller MFC supplies the film formation area 21a with at least either one of krypton (Kr) and xenon (Xe) as processing gas. In one embodiment, the film formation process using Kr or Xe as the processing gas is referred to as a Kr process or an Xe process, respectively. A film formation process using Ar as a processing gas is referred to as an Ar process.

Further, the chamber main body 21 is connected via a discharge gas pipe 23 to a discharge unit PU, which forms a pressure reduction unit. The discharge unit PU is a discharge system formed by a turbo molecular pump or a rotary pump and reduces the pressure of the film formation area 21a, which is supplied with the processing gas, to a predetermined pressure. In one embodiment, the pressure of the film formation area 21a is referred to as the processing pressure P_{S}. The processing pressure P_{S} is 0.1 (Pa) or lower and preferably 0.1 (Pa) to 0.04 (Pa). When the processing chamber P_{S} becomes higher than 0.1 (Pa), it becomes difficult to obtain a uniform antiferromagnetic layer composition and a uniform film thickness. Further, when the processing pressure P_{S} becomes lower than 0.02 (Pa), plasma stability in the film formation area 21a is dissipated.

The film formation area 21a of the chamber main body 21 includes a substrate holder 24, which forms a heating unit, and a lower adhesion prevention plate 25. The substrate holder 24 includes a heater (not shown), heats the received substrates S to a predetermined layer, and positions and fixes the substrates S. In one embodiment, the temperature of a substrate S during film formation is referred to as a substrate temperature T_{sub}. The substrate temperature T_{sub} is higher than 20° and preferably 100° C. to 400° C. When the substrate temperature T_{sub} becomes 100° C. or lower, it becomes difficult to obtain an L1₂ ordered phase. When the substrate temperature T_{sub} becomes higher than 400° C., underlayers such as the substrates S are thermally damaged.

The substrate holder 24, which is driven by and coupled to an output shaft of a holder motor 26, is rotated about a center axis A to rotate the substrates S in the circumferential direction. The substrate holder 24 scatters sputtering grains, which are delivered in a single direction, along the entire circumference of the substrate S to improve the in-plane uniformity of deposits. The lower adhesion prevention plate 25 extends around the substrate holder 24 and prevents the sputtering grains from adhering to the inner wall forming the film formation area 21a.

The chamber main body 21 includes a plurality of cathodes 27 located diagonally above the substrate holder 24. In one embodiment, as viewed in FIG. 2, the left cathode 27 is referred to as a first cathode 27a, and the right cathode 27 is referred to as a second cathode 27b.

Each cathode 27 includes a packing plate 28 and is connected to an external power supply (not shown) via the corresponding packing plate 28. Each external power supply supplies the corresponding packing plate 28 with predetermined DC power. In one embodiment, the density of the power supplied to each packing plate 28 is referred to as the applied power density P_{D}. The applied power density P_{D} is set so that the composition ratio X of the antiferromagnetic layer is in the range of 20(atom %)≦X≦30(atom %).

Each cathode 27 includes a target T located at the lower side of the corresponding packing plate 28. The main component of the target T for the first cathode 27a is the element forming the underlayer electrode layer, and the main component of the target T for the second cathode 27b is the element forming the antiferromagnetic layer. The target T for the second cathode 27b is one of which element is the same as the element forming the antiferromagnetic layer and which includes 60 (atom %) to 90 (atom %) of manganese (Mn), which is the main component of the antiferromagnetic layer.

Each target T is disk-shaped and exposed in the film formation area 21a. Further, a line normal to the inner surface of each target T is inclined by a predetermined angle (e.g., 22°) relative to a line normal (center axis A) to the substrate S. In one embodiment, the target T of the first cathode 27a is referred to as a first target T1, and the target T of the second cathode 27b is referred to as a second target T2.

Each cathode 27 includes a magnetic circuit MG and a cathode motor M, which are arranged at the upper side of the corresponding packing plate 28. Each magnetic circuit MG forms a magnetron field along the inner surface of the corresponding target T and generates highly dense plasma near the target T. Each magnetic circuit MG is driven by and coupled to an output shaft of the corresponding cathode motor M. When the cathode motor M is driven, the magnetic circuit MG is rotated along the planar direction of the corresponding target T. Each cathode motor M moves the magnetron field of the corresponding magnetic circuit MG along the entire circumference of the corresponding target T to improve the erosion uniformity.

An upper adhesion prevention plate 29 is arranged on the film formation area 21a of the chamber main body 21. The upper adhesion prevention plate 29 is arranged so as to entirely cover the upper side of the film formation area 21a and prevent the sputtering grains from adhering to the inner wall forming the film formation area 21a. The upper adhesion prevention plate 29 includes shutters 29a, which are arranged at regions facing each target T. When the corresponding target T is supplied with predetermined power, each shutter 29a opens an opening, which faces the target T, and enables sputtering to be performed with the target T. Further, when the corresponding target T is not supplied with power, each shutter 29a closes the opening, which faces the target T, and disables sputtering with the target T.

When starting the film formation process on the underlayer electrode layer and the antiferromagnetic layer, the control device 13 drives and controls the mass flow controller MFC and supplies the film formation area 21a with at least either one of Kr and Xe. Further, the control device 13 drives and controls the discharge unit PU to adjust the pressure of the film formation area 21a to 0.1 (Pa) or less and form a lower pressure atmosphere. The control device 13 drives and controls the holder motor 26 and the first cathode 27a to sputter the first target T1. Then, the control device 13 drives and controls the holder motor 26 and the second cathode 27b to sputter the second target T2. That is, the control device 13 sputters the first target T1 and the second target T2 under a low-pressure atmosphere including at least either one of Kr and Xe to superimpose an underlayer electrode layer and an antiferromagnetic layer on a substrate S, which has been heated to a predetermined temperature.

When the processing gas collides against target atoms head-on, generally, the energy of recoil particles having a scattering angle of 90° and the energy of recoil particles having a scattering angle of 180° are respectively expressed by V_{C}·(M_{T}−M_{G})/(M_{T}+M_{G}) and V_{C}·(M_{T}−M_{G})²/(M_{T}+M_{G})². Here, V_{C} expresses the acceleration voltage applied to the target surface of the processing gas, and M_{T} and M_{G} respectively express the target atom mass and the processing gas mass.

The mol mass of Ar atoms is 40.0 (g/mol), whereas the mol mass of Kr atoms and Xe atoms are respectively 83.8 (g/mol) and 131.30 (g/mol). The energy of recoil particles is decreased by using a Kr process or an Xe process compared to that when using an Ar process. Thus, the Kr process or Xe process decreases the quantity and energy of recoil particles, which hinder the L1₂ ordered phase, and reduces damages to the L1₂ ordered phase. The Kr process or Xe process enhances the formation of the L1₂ ordered phase for an antiferromagnetic layer so that a superimposed film of the antiferromagnetic layer and fixed layer have a higher unidirectional anisotropy constant J_{K}.

### Example

An example will now be used to describe the present invention.

First, a silicon wafer having a diameter of 200 mm was used as a substrate. A film formation process was performed on the substrate S by the manufacturing apparatus 10 to obtain a superimposed film of Ta (5 nm)/Ru (20 nm)/MnIr (10 nm)/CoFe (4 nm)/Ru (1 nm)/Ta (2 nm).

In detail, the antiferromagnetic layer chamber F1 was used to superimpose a Ta film having a thickness of 5 nm and an Ru film having a thickness of 20 nm, and then an MnIr film having a thickness of 10 nm was formed to obtain the antiferromagnetic layer. An alloy target of which composition was Mn₇₇Ir₂₃ and having a diameter of 125 mm was used as the second target T2. The distance between the substrate S and the target T was set as 200 mm in the normal direction of each target T. Further, Kr was used as the processing gas.

Next, the fixed layer chamber F2 and the free layer chamber F4 were used to form a CO₇₀Fe₃₀ film having a thickness of 4 nm and obtain a fixed layer, and then an Ru film having a thickness of 1 nm and a Ta film having a thickness of 2 nm were formed to obtain a protective layer.

The temperature of the substrate was adjusted to 20° C. when forming the underlayer, the fixed layer, and the protective layer. The substrate temperature T_{sub} when forming the antiferromagnetic layer was adjusted to 350° C., the applied power density P_{D} for the target was adjusted to 2.04 (W/cm²), and the processing pressure P_{S} was adjusted to 0.04 (Pa) to obtain the superimposed film of the example.

Further, when forming the antiferromagnetic layer, at least one of the substrate temperature T_{sub}, the applied power density P_{D}, the processing process P_{S}, and the processing gas was changed and the remaining ones were left to be the same as the example to obtain superimposed films for comparative examples.

Substrate Temperature T_{sub}: 20(° C.), 200(° C.), 250(° C.), 400(° C.)

Applied Power Density P_{D}: 0.41 (W/cm²), 0.81 (W/cm²), 1.22 (W/cm²), 1.63 (W/cm²), 2.44 (W/cm²)

Processing Pressure P_{S}: 0.1 (Pa), 0.2 (Pa), 0.4 (Pa), 1.0 (Pa), 2.0 (Pa)

Processing Gas: Ar

For each superimposed film, a magnetic hysteresis curve was obtained under room temperature to calculate a unidirectional anisotropy constant J_{K} of the superimposed film. Further, the sheet resistance value was measured under room temperature for each superimposed film to calculate the resistance uniformity of each superimposed film. The unidirectional anisotropy constant J_{K} was calculated as J_{K}=M_{S}·d_{F}·Hₑₓ. Here, Hₑₓ expresses the magnitude of the shift magnetic field toward the applied magnetic field direction in the magnetic hysteresis curve (hereinafter simply referred to as exchange-coupled magnetic field Hₑₓ). Further, M_{S} and d_{F} respectively express the saturated magnetization M_{S} of the fixed layer (Co₇₀Fe₃₀ film) and the thickness d_{F} of the fixed layer.

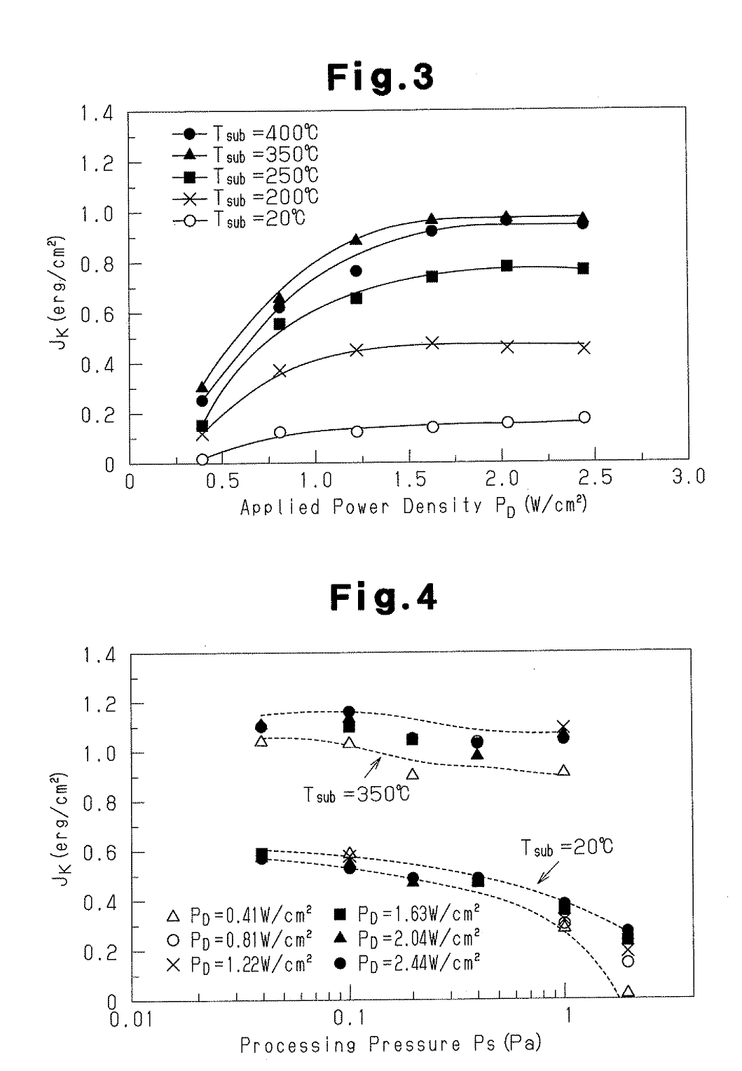

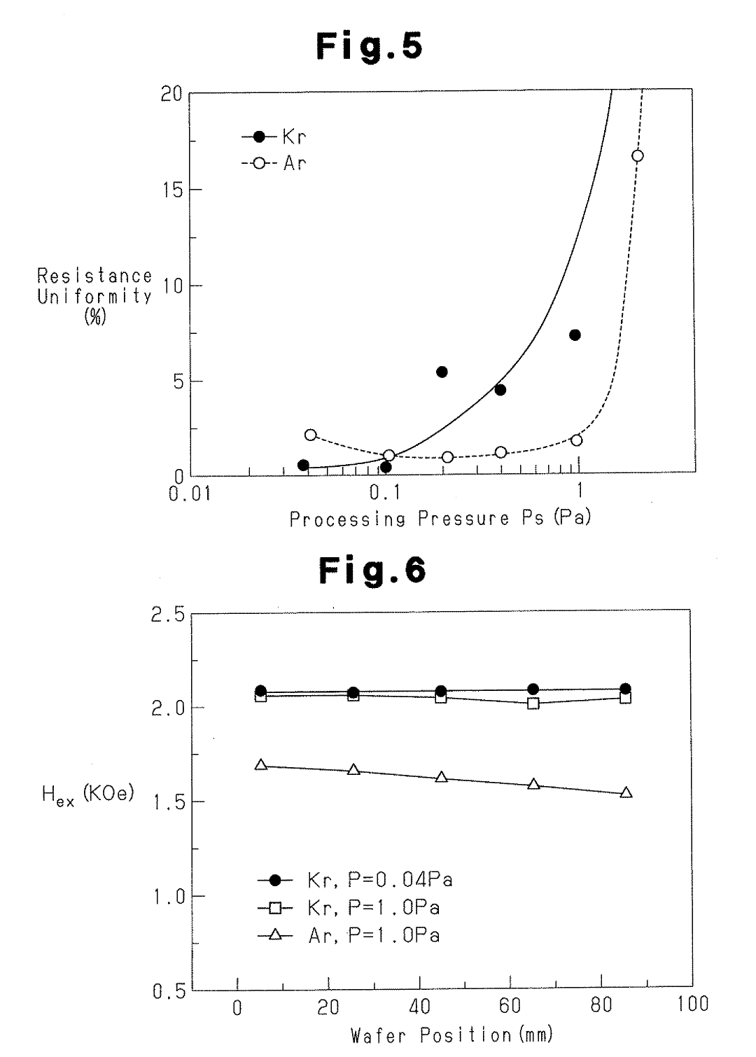

FIG. 3 shows the dependency of the unidirectional anisotropy constant J_{K} on the applied power density P_{D}, and FIG. 4 shows the dependency of the unidirectional anisotropy constant J_{K} on the processing pressure P_{S}. In FIG. 3, the processing pressure P_{S} for the unidirectional anisotropy constant J_{K} is 2.0 (Pa), and the substrate temperature T_{sub} in FIG. 4 is 20° C. and 350° C. Further, FIG. 5 shows the dependency of the resistance uniformity in a wafer plane on the processing pressure P_{S}, and FIG. 6 shows the dependency of the resistance uniformity of an exchange-coupled magnetic field Hₑₓ on the processing pressure P_{S}.

In FIG. 3, the unidirectional anisotropy constant J_{K} increases as the applied power density P_{D} increases. When the applied power density P_{D} is the same, the unidirectional anisotropy constant J_{K} increases as the substrate temperature T_{sub} rises. In the same manner as in an Ar process (refer to FIG. 8), such dependency on the applied power density P_{D} suggests that the increase in the applied power density P_{D} causes the composition of the MnIr film to become closer to Mn₃Ir. Further, the dependency on the substrate temperature T_{sub} suggests that a rise in the substrate temperature T_{sub} enhances the formation of the L1₂ ordered phase.

Accordingly, the Kr process obtains a composition and crystallinity that are suitable for obtaining the L1₂ ordered phase by selecting the appropriate applied power density P_{D} and substrate temperature T_{sub}, for example, a substrate temperature of 350° C. and an applied power density P_{D} of 2.04 (W/cm²).

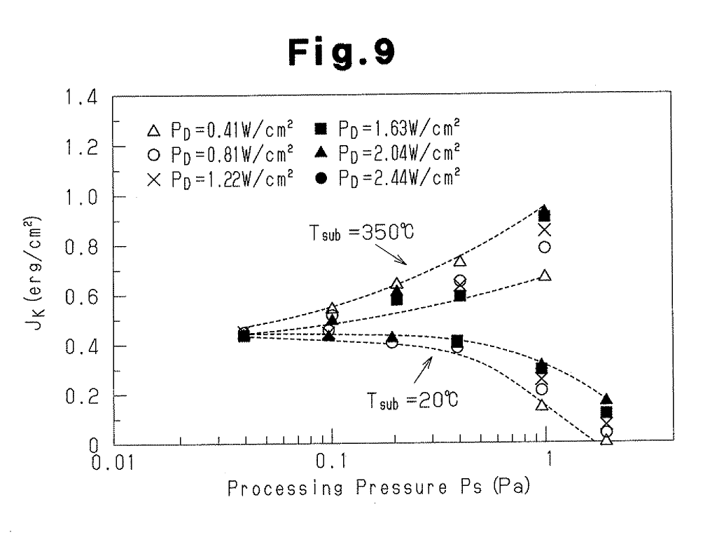

In FIG. 4, when the substrate temperature T_{sub} is 350° C., the unidirectional anisotropy constant J_{K} takes a high value near 1.0 (erg/cm²) regardless of the processing pressure P_{S}. The unidirectional anisotropy constant J_{K} in this low-pressure process differs significantly from the Ar process (refer to FIG. 9) and suggests that the formation of the L1₂ ordered phase L1₂ is greatly enhanced. In contrast, when the substrate temperature T_{sub} is 20° C., the unidirectional anisotropy constant J_{K} has about the same dependency as the Ar process (refer to FIG. 9). However, the unidirectional anisotropy constant J_{K} of the Kr process is approximately 0.6 (erg/cm²) and takes a higher value than that of the Ar process under a low pressure (refer to FIG. 9). That is, the Kr process enhances the formation of the L1₂ ordered phase in accordance with the composition and crystallinity obtained from the applied power density P_{D}, the substrate temperature T_{sub}, and the processing chamber P_{S}.

Accordingly, in comparison with the Ar process, when the processing pressure P_{S} is 0.1 (Pa) or lower, the Kr process increases the unidirectional anisotropy constant J_{K} more than the Ar process, and the unidirectional anisotropy constant J_{K} may be further increased by heating the substrate S. In the Kr process, when the processing pressure P_{S} is 0.1 (Pa) or lower and the substrate temperature T_{sub} is 100° C. or higher, a high unidirectional anisotropy constant J_{K} that is close to 1.0 (erg/cm²) may be obtained.

As shown in FIG. 5, when the processing pressure P_{S} is 0.1 (Pa) or lower, the resistance uniformity of the superimposed film is 1% to 2% at to in the Ar process, and 1.0% or less in the Kr process. When the processing temperature P_{S} is 0.1 to 1.0 (Pa), the resistance uniformity of the superimposed film is maintained at approximately 1.0% in the Ar process, whereas it is increased to approximately 5% in the Kr process. When the processing pressure P_{S} exceeds 1.0 (Pa), the resistance uniformity of the superimposed film increases to a value that exceeds 10% regardless of the type of processing gas. The dependency on the processing pressure P_{S} suggests that the decrease in the film formation speed as the mean free path decreases and the difference in the scattering probability of the sputtering particles increases the film thickness difference and composition ratio difference in a wafer plane and greatly deteriorates the resistance uniformity of the superimposed film.

Accordingly, when the processing pressure P_{S} is 0.1 (Pa) or lower, the Kr process increases the unidirectional anisotropy constant J_{K} and obtains satisfactory uniformity for the film thickness and composition in a wafer plane.

As shown in FIG. 6, when the processing pressure P_{S} of the Kr process is 0.04 (Pa), the exchange-coupled magnetic field Hₑₓ of the superimposed film takes a generally constant value between the wafer positions of 5 mm to 85 mm, that is, between the central part and rim of the wafer. When the processing pressure P_{S} of the Kr process is 1.0 (Pa), a slight difference occurs in the exchange-coupled magnetic field Hₑₓ of the superimposed film between the central part and rim of the wafer. In contrast, when the processing pressure P_{S} of the Ar process is 1.0 (Pa), the exchange-coupled magnetic field Hₑₓ of the superimposed film becomes smaller in the radial direction from the wafer center and thereby causes large variations in the wafer plane. In the same manner as described above, the processing pressure P_{S} and the dependency on the processing gas suggests that the decrease in the film formation speed as the mean free path decreases and the difference in the scattering probability of the sputtering particles increases the film thickness difference and composition ratio difference in a wafer plane and greatly deteriorates the resistance uniformity of the superimposed film.

Accordingly, when the processing pressure P_{S} is 0.1 (Pa) or lower, the Kr process increases the unidirectional anisotropy constant J_{K} and obtains satisfactory uniformity for the film thickness and composition in a wafer plane.

### [Magnetic Device]

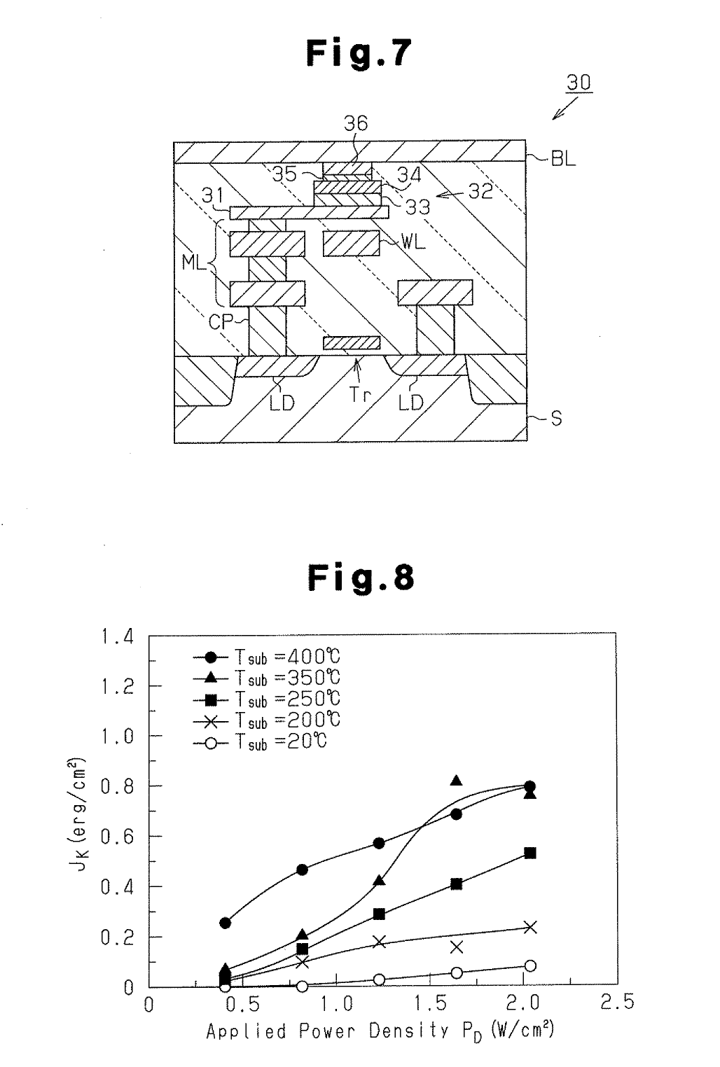

A magnetic memory 30 serving as a magnetic device manufactured with the magnetic device manufacturing apparatus 10 will now be discussed. FIG. 7 is a schematic cross-sectional diagram of the magnetic memory 30.

A thin film transistor Tr is formed on the substrate S of the magnetic memory 30. The thin film transistor Tr includes a diffusion layer LD connected via a contact plug CP, a wire ML, and a lower electrode layer 31 to a magnetoresistance element 32. The magnetoresistance element 32 is a TMR element including an antiferromagnetic layer 33, a fixed layer 34, a non-magnetic layer 35, and a free layer 36, which are superimposed on the upper side of the lower electrode layer 31.

A word line WL spaced downward from the lower electrode layer 31 is arranged at the lower side of the magnetoresistance element 32. The word line WL is strip-shaped and formed to extend in a direction orthogonal to the plane of the drawing. A strip-shaped bit line BL arranged on the upper side of the magnetoresistance element 32 extends in a direction perpendicular to the word line WL. Thus, the magnetoresistance element 32 is arranged between the word line WL and the bit line BL, which are perpendicular to each other.

The magnetoresistance element 32 is formed with the manufacturing apparatus 10 by superimposing the lower electrode layer 31, the antiferromagnetic layer 33, the fixed layer 34, the non-magnetic layer 35, and the free layer 36 and etching each layer. The magnetoresistance element 32 manufactured with the manufacturing apparatus 10 stabilizes the unidirectional anisotropy constant J_{K} of the antiferromagnetic layer 33/fixed layer 34 at a high level of approximately 1.0 (erg/cm²) and improves the thickness uniformity of the antiferromagnetic layer 33. As a result, the device characteristics of the magnetic memory 30 are improved.

The manufacturing apparatus 10 (manufacturing method) of the embodiment and the magnetic device manufactured by the manufacturing apparatus 10 has the advantages described below.

(1) The manufacturing apparatus 10 heats the substrate S placed on the substrate holder 24 in the film formation area 21a to a predetermined temperature and reduces the processing pressure P_{S} to 0.1 (Pa) or lower. Further, the manufacturing apparatus 10 sputters the second target T2, the main components of which are the elements forming the antiferromagnetic layer, by using at least either one of Kr and Xe as the processing gas to form the antiferromagnetic layer.

When using Ar as the processing gas as in the prior art, the mean free path of the Ar particles, which recoil during sputtering, increases as the processing pressure P_{S} becomes lower. The recoiling Ar particles, which refer to the Ar particles in which the Ar ions that collide against a target during sputtering, do not sputter the elements forming the target, dissipate charge, and become scattered. In a low-pressure process, the recoil AT particles having higher kinetic energy are emitted against the antiferromagnetic layer on the substrate. The emission of the recoil Ar particles physically etches the elements forming the target (e.g., Mn atoms, Ir atoms, and the like) from the L1₂ ordered phase, which grows on the substrate, and greatly damages the L1₂ ordered phase. The invention of the present invention has focused on the damage of the L1₂ ordered phase caused by the recoil Ar particles as one factor of the low-pressure process lowering the unidirectional anisotropy constant J_{K}. While examining the lowered energy of recoiling process gas particles, the inventor of the present invention has found that when at least either one of Kr and Xe is used as the processing gas, the unidirectional anisotropy constant J_{K} has a high level of approximately 1.0 (erg/cm²) regardless of the processing pressure P_{S}.

Accordingly, the use of at least either one of Kr and Xe as the processing gas enhances the growth of the L1₂ ordered phase. As a result, in a low-pressure process in which the pressure during sputtering is 0.1 (Pa) or less, the unidirectional anisotropy constant J_{K} is increased, and the uniformity of the composition and thickness of the antiferromagnetic layer is improved. As a result, the magnetic characteristics of the magnetic device are improved.

(2) The manufacturing apparatus 10 heats the substrate S to a predetermined temperature (preferably, 100° C. to 400° C.) to form the antiferromagnetic layer. Accordingly, in a low-pressure process in which the pressure during sputtering is 0.1 (Pa) or less, the growth of the L1₂ ordered phase is enhanced in an ensured manner.

The above-described embodiment may be modified as described below.

The processing gas of the above-described embodiment may be a gas mixture of Kr and Xe or a gas including at least either one of Kr and Xe.

In the above-described embodiment, the antiferromagnetic layer chamber F1 is a DC magnetron sputtering device. However, the present invention is not limited in such a manner. For example, the antiferromagnetic layer chamber F1 may be of an RF magnetron type or have a structure that does not use the magnetic circuit MG.

In the above-described embodiment, the magnetic device is the magnetic memory 30. However, the present invention is not limited in such a manner. For example, the magnetic device may be a magnetic sensor or a magnetic reproduction head as long as it is a magnetic device including an antiferromagnetic layer of an L1₂ ordered phase.

1. A magnetic device manufacturing method for manufacturing a magnetic device, the magnetic device manufacturing method comprising:
providing a substrate;
arranging the substrate in a film formation chamber;
heating the substrate to a predetermined temperature;
reducing the pressure of the film formation chamber to 0.1 (Pa) or lower; and
forming an antiferromagnetic layer on the substrate in the film formation chamber of which the pressure is reduced, by sputtering a target of which a main component is an element forming the antiferromagnetic layer with at least either one of Kr and Xe, with the antiferromagnetic layer including an L1₂ ordered phase expressed by compositional formula Mn_{100-X}-M_{X}, wherein M is at least one element selected from the out consisting of Ru, Rh, Ir, and Pt, and X is 20(atom %)≦X≦30(atom %)).

2. The magnetic device manufacturing method according to claim 1, wherein said forming the antiferromagnetic layer includes forming the antiferromagnetic layer on the substrate after the substrate has been heated to a temperature of from 100° C. to 400° C.

3. A magnetic device manufacturing apparatus for manufacturing a magnetic device using a substrate, the magnetic device manufacturing apparatus comprising:
a film formation chamber that accommodates the substrate;
a pressure reduction unit that reduces pressure in the film formation unit;
a heating unit that heats the substrate in the film formation chamber;
a cathode including a target of which a main component is an element forming the antiferromagnetic layer;
a supply unit that supplies the film formation chamber with at least either one of Kr and Xe;
a control unit that drives the heating unit to heat the substrate to a predetermined temperature, drives the pressure reduction unit to reduce the pressure of the film formation chamber to 0.1 (Pa) or lower, drives the supply unit to supply the film formation chamber with at least either one of Kr and Xe, and drives the cathode to sputter the target and form the antiferromagnetic layer on the substrate in the film formation chamber of which the pressure is reduced, with the antiferromagnetic layer including an L1₂ ordered phase expressed by compositional formula Mn_{100-X}-M_{X}, wherein M is at least one element selected from the group consisting of Ru, Rh, Ir, and Pt, and X is 20(atom %)≦X≦30(atom %).

4. The magnetic device manufacturing apparatus according to claim 3, wherein the control unit drives the heating unit to heat the substrate to a temperature of from 100° C. to 400° C.

5. A magnetic device comprising:
an antiferromagnetic layer including an L1₂ ordered phase expressed by compositional formula Mn_{100-X}-M_{X} in which M is at least one element selected from the group consisting of Ru, Rh, Ir, and Pt, and X is 20(atom %)≦X≦30(atom %);
wherein the antiferromagnetic layer is manufactured by the magnetic device manufacturing apparatus according to claim 3.

6. A magnetic device comprising:
an antiferromagnetic layer including an L1₂ ordered phase expressed by compositional formula Mn_{100-X}-M_{X} in which M is at least one element selected from the group consisting of Ru, Rh, Ir, and Pt, and X is 20(atom %)≦X≦30(atom %);
wherein the antiferromagnetic layer is manufactured by the magnetic device manufacturing apparatus according to claim 4.
